(19) United States
(12) Patent Application Publication
(10) Pub. No.: US 2025/0294729 A1
(43) Pub. Date: Sep. 18, 2025

(54) Memory Circuitry And Methods Used In Forming Memory Circuitry

(71) Applicant: Micron Technology, Inc., Boise, ID (US)

(72) Inventors: Dojun Kim, Boise, ID (US); Jake Soares, Boise, ID (US); Ting Zhao, Meridian, ID (US); Albert Liao, Boise, ID (US)

(73) Assignee: Micron Technology, Inc., Boise, ID (US)

(21) Appl. No.: 19/044,915

(22) Filed: Feb. 4, 2025

Related U.S. Application Data
(60) Provisional application No. 63/564,143, filed on Mar. 12, 2024.

(51) Int. Cl. H10B 12/00; H10D 64/66

(52) U.S. Cl. CPC H10B 12/50; H10B 12/05; H10B 12/09; H10B 12/488; H10D 64/665; H10D 64/667

(57) ABSTRACT

Memory circuitry comprises vertically-alternating tiers of insulative material and memory cells. The memory cells individually comprise a horizontal transistor comprising a gate. The gate comprises part of a one of a plurality of horizontal conductive access lines that individually directly electrically couple together multiple of the gates of different ones of the horizontal transistors that are in the same memory-cell tier. The gates and access lines individually comprise conductive first and second different composition metal materials that are laterally aside and directly against one another. Methods are disclosed.

### TECHNICAL FIELD

Embodiments disclosed herein pertain to memory circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

Memory cells may be arranged or arrayed in several manners including, for example, in a vertical stack (e.g., along a z direction) comprising a three-dimensional (3D) memory array region having horizontal tiers in which individual memory cells are received (e.g., arrayed in x and y directions). The stack in the 3D memory array region comprises vertically-alternating insulative tiers and conductive tiers (e.g., as part of memory-cell tiers) that extend into a stair-step region. The stair-step region includes individual “stairs” (alternately termed “steps” or “stair-steps”) that define contact regions of conductive lines of individual of the conductive tiers to which vertical conductive vias can contact to provide electrical access to/from those conductive lines.

### BRIEF DESCRIPTION OF THE DRAWINGS

FIG. 1 is a diagrammatic schematic of a DRAM memory array and peripheral circuitry in accordance with the prior art and in accordance with an embodiment of the invention.

FIG. 2 is an enlargement of a portion of FIG. 1.

FIGS. 3-7 are diagrammatic sectional views of constructions in accordance with embodiments of the invention.

FIGS. 8-20 are diagrammatic sequential sectional and/or enlarged views of the construction of FIGS. 3-7, or portions thereof or alternate and/or additional embodiments, in process in accordance with some embodiments of the invention.

### DETAILED DESCRIPTION OF EXAMPLE EMBODIMENTS

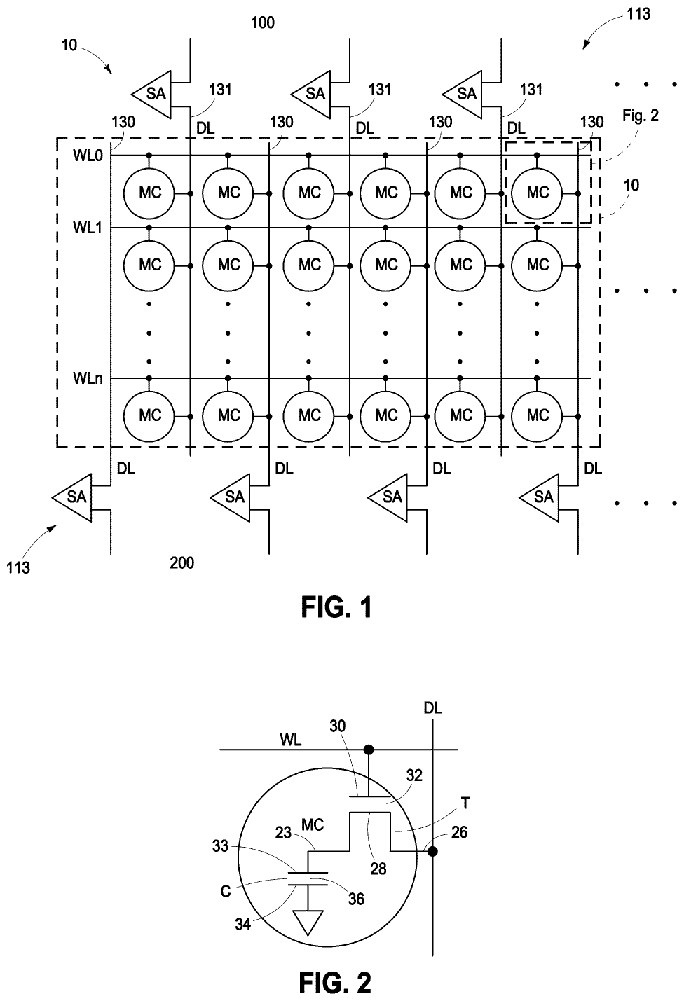

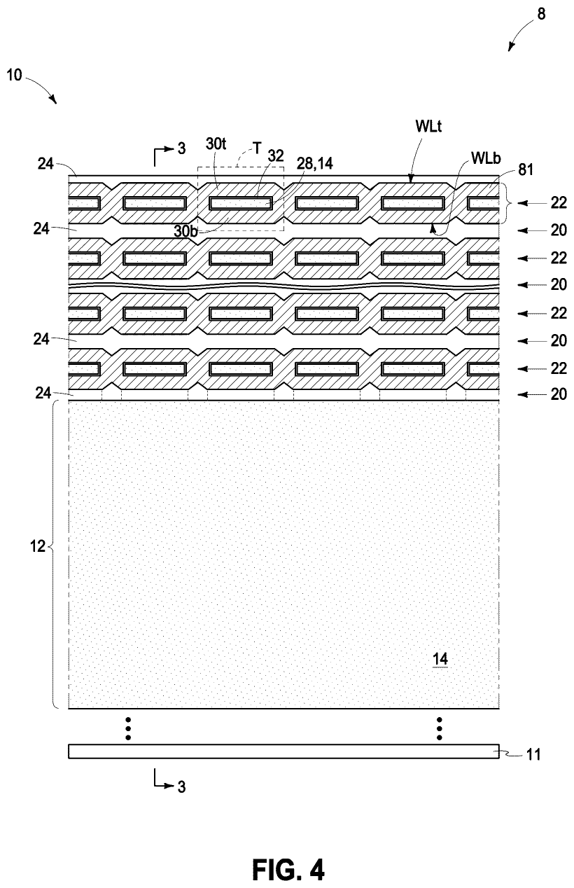

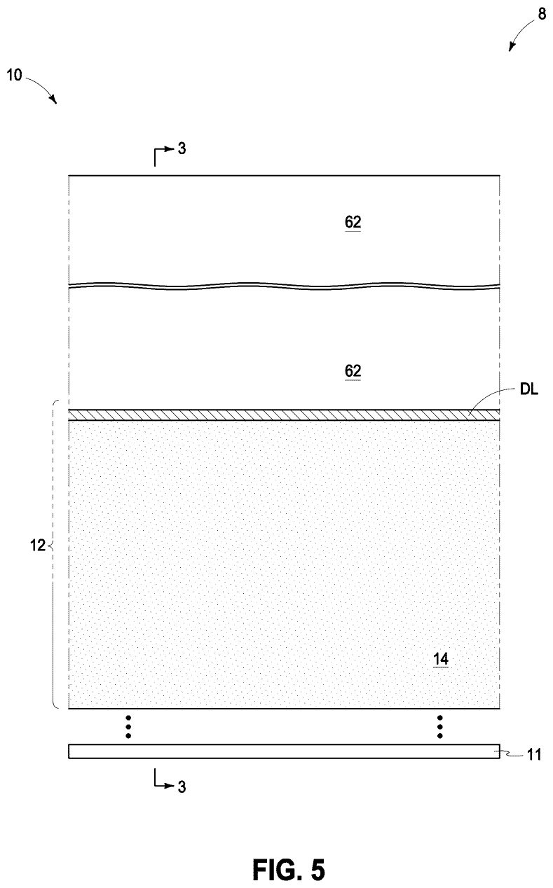

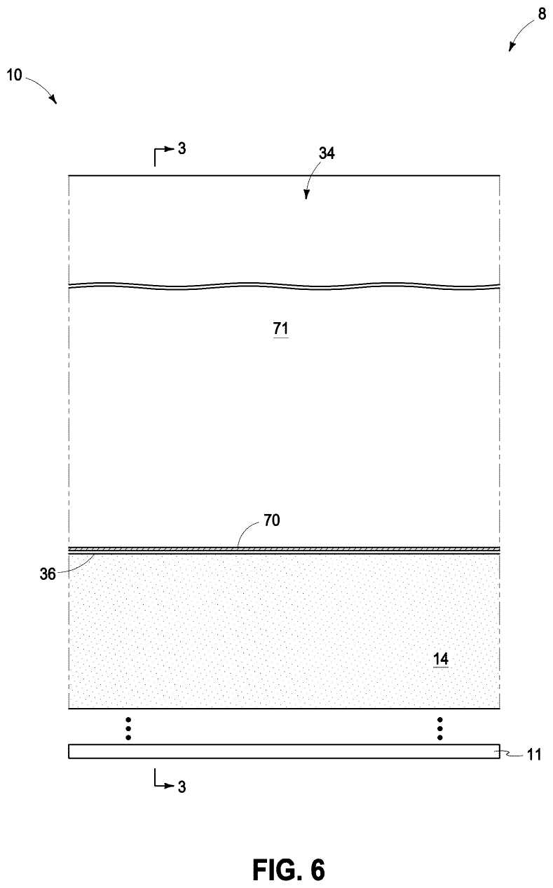

Embodiments of the invention encompass memory circuitry (e.g., DRAM) having vertically-alternating tiers of insulative material and memory cells, with the memory cells individually comprising a capacitor and a horizontally-oriented transistor. Embodiments of the invention also encompass methods used in forming such memory circuitry. Example structure embodiments are first described with reference to FIGS. 1-20.

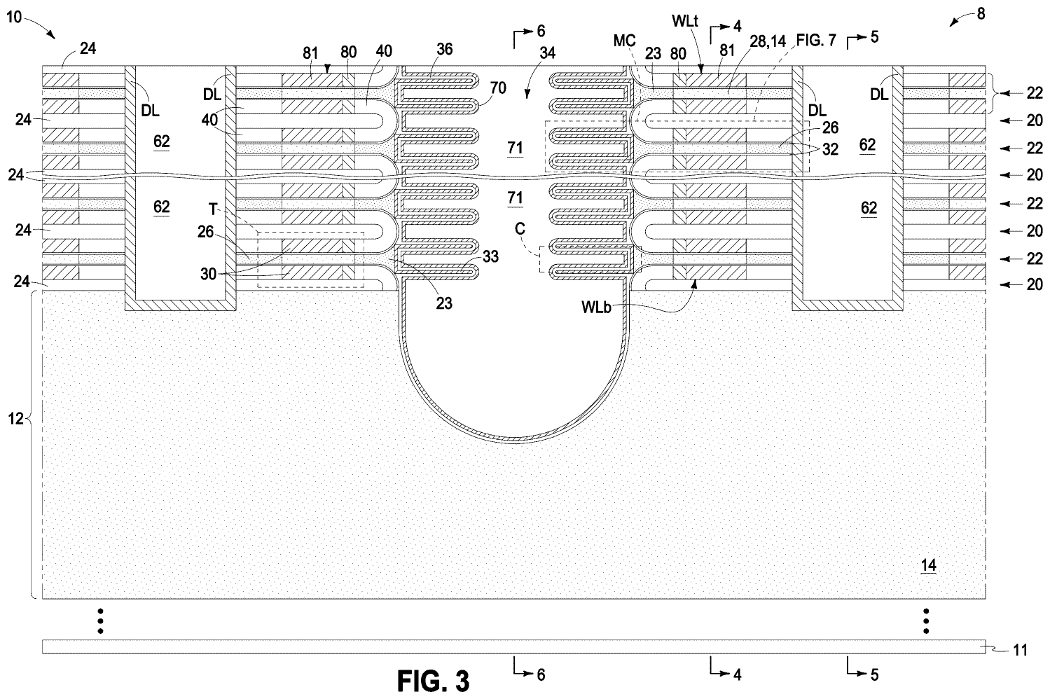

One example prior art schematic diagram of DRAM circuitry, and in accordance with an embodiment of the invention, is shown in FIGS. 1 and 2. FIG. 2 shows example memory cells MC individually comprising a transistor T and a capacitor C. One electrode of capacitor C is directly electrically coupled to a suitable potential (e.g., ground) and the other capacitor electrode is contacted with or comprises one of the source/drain regions of transistor T. The other source/drain region of transistor T is directly electrically coupled with a digitline/sense line 130 or 131 (also individually designated as DL). The gate of transistor T is directly electrically coupled with (e.g., comprises part of) a wordline/access line WL. FIG. 1 shows digitlines 130 and 131 extending from one of opposite sides 100 and 200 of a memory array area 10 into a peripheral circuitry area 113 that is aside memory array area 10. Digitlines 130 and 131 individually directly electrically couple with a sense amp SA on opposite sides 100 and 200 of array area 10 within peripheral circuitry area 113. Non-schematic structure embodiments as shown herein in FIGS. 3+ have the wordlines/access lines running horizontally and the digitlines/sense lines running vertically. Further, and by way of example only, sense amps SA could be on only one side or all directly above or directly below memory array area 10.

Referring to FIG. 3-7, an example fragment of a substrate construction 8 comprising array or array area 10 has been fabricated relative to a base substrate 11. Substrate 11 may comprise any one or more of conductive/conductor/conducting, semiconductive/semiconductor/semiconducting, and insulative/insulator/insulating (i.e., electrically herein) materials. Materials may be aside, elevationally inward, or elevationally outward of the FIG. 3-depicted materials. For example, other partially or wholly fabricated components of integrated circuitry may be provided somewhere above, about, or within base substrate 11. Control and/or other peripheral circuitry for operating components within a memory array may also be fabricated and may or may not be wholly or partially within a memory array or sub-array. Further, multiple sub-arrays may also be fabricated and operated independently, in tandem, or otherwise relative one another. As used in this document, a “sub-array” may also be considered as an array.

Memory circuitry (e.g., that of or comprising construction 8) comprises vertically-alternating tiers 20, 22 of insulative material 24 (e.g., silicon dioxide and/or silicon nitride) and memory cells MC, respectively. Example construction 8 comprises a semiconductor substrate 12 (e.g., a bulk wafer comprising monocrystalline silicon 14) above which tiers 20 and 22 are received. Regardless, memory cells MC individually comprise a horizontal transistor T, for example comprising a first source/drain region 23, a second source/drain region 26, and a channel region 28 horizontally between the first and second source/drain regions. Regions 23, 26, and 28 of different immediately-horizontally-adjacent memory cells MC into and out of the plane of the page upon which FIG. 3 lies in a common memory-cell tier 22 may be isolated relative one another by insulative material (not shown). Transistor T also comprises a gate 30* (e.g., gate-all-around the channel; e.g., conductive metal material) having a gate insulator 32 (e.g., dielectric or ferroelectric) between at least channel region 28 and gate 30* (an * being used as a suffix to be inclusive of all such same-numerically-designated structures or portions thereof that may or may not have other suffixes). Gate 30* comprises part of a one of a plurality of horizontal conductive access lines WL* that individually directly electrically couple together multiple gates 30* of different ones of horizontal transistors T that are in the same memory-cell tier 22. An example insulator material 40 (e.g., silicon nitride) is laterally against lateral sides/edges of gates 30*. In one embodiment and as shown, gate 30* comprises part of a top gate 30t that is part of a top access line WLt and comprises part of a bottom gate 30b that is part of a bottom access line WLb.

Example capacitor C comprises a first capacitor electrode 33 (e.g., a storage-node electrode), a second capacitor electrode 34 (e.g., comprising conductive metal material 70 and conductively-doped polysilicon 71), and a capacitor insulator 36 there-between (e.g., dielectric or ferroelectric). Second capacitor electrodes 34 of multiple capacitors C are directly electrically coupled with one another. First capacitor electrode 33 is directly coupled to first source/drain region 23 of transistor T. Digitlines DL extend through vertically-alternating tiers 20 and 22. Digitlines DL of different immediately-horizontally-adjacent memory cells MC into and out of the plane of the page upon which FIG. 3 lies in a common memory-cell tier 22 may be isolated relative one another by insulative material (not shown). Individual second source/drain regions 26 of individual transistors T that are in different memory-cell tiers 22 are directly electrically coupled to individual digitlines DL. Example insulator material 62 (e.g., silicon dioxide and/or silicon nitride) is between immediately-adjacent digitlines DL.

Gates 30* and access lines WL* individually comprise conductive first and second different composition metal materials 80 and 81, respectively, that are laterally aside and directly against one another (e.g., conductive first and second metal materials 80 and 81 being laterally aside and directly against one another in each of top and bottom gates 30t, 30b and access lines WLt, WLb). Any different composition conductive metal materials may be used, with a particular ideal example comprising titanium nitride for one of conductive first metal material 80 and conductive second metal material 81 and elemental-form molybdenum for the other. By way of examples only, others materials 80 and/or 81 include Ru, W, Co, and nitrides thereof. In one embodiment, at least one of conductive first and second metal materials 80 and 81 (each as shown) spans a total thickness TT of individual gates 30* and access lines WL*.

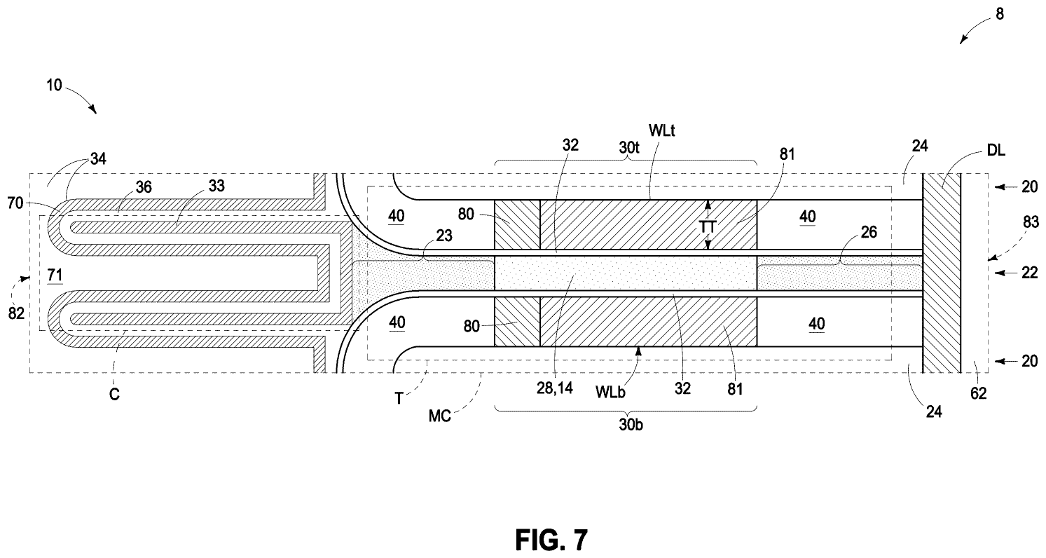

In one particular embodiment, conductive first and second metal materials 80 and 81 have different volumes relative one another. In one such particular embodiment, memory cells MC individually comprise two laterally-opposing sides 82, 83. One of sides 82, 83 (e.g., 82 in FIG. 7) comprises capacitor C. Transistor C on other the other of sides 82, 83 (e.g., 83 in FIG. 7) is directly electrically coupled to a digitline DL (e.g., via source/drain region 26). The larger of the two volumes (e.g., 81) is closer to the digitline DL than to capacitor C. In one embodiment of such particular embodiment, conductive second metal material 81 has greater electrical conductivity than conductive first metal material 80 and is the larger of the two volumes. In one embodiment of such particular embodiment, one of first and second conductive metal materials 80, 81 comprises elemental-form molybdenum and the other comprises titanium nitride, with the larger of the two volumes comprising the elemental-form molybdenum and the smaller of the two volumes comprising the titanium nitride.

Any other attribute(s) or aspect(s) as shown and/or described herein with respect to other embodiments may be used in the embodiments shown and described with reference to the above embodiments.

Embodiments of the invention encompass methods used in forming memory circuitry, by way of example only that incorporates device/structure as referred to above. Nevertheless, the method embodiments may incorporate, form, and/or have any of the attributes described with respect to device embodiments.

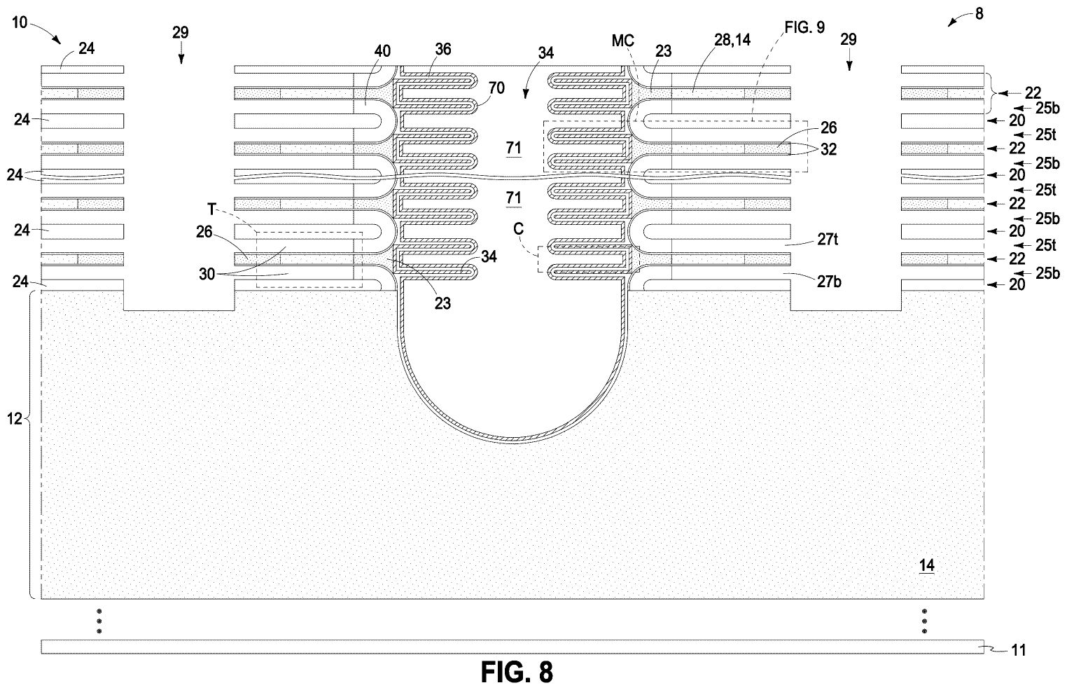

FIGS. 8-15 by way of example sequentially show predecessor constructions 8 in a first example method used in forming memory circuitry, with such circuitry comprising memory cells that individually comprise a horizontal transistor.

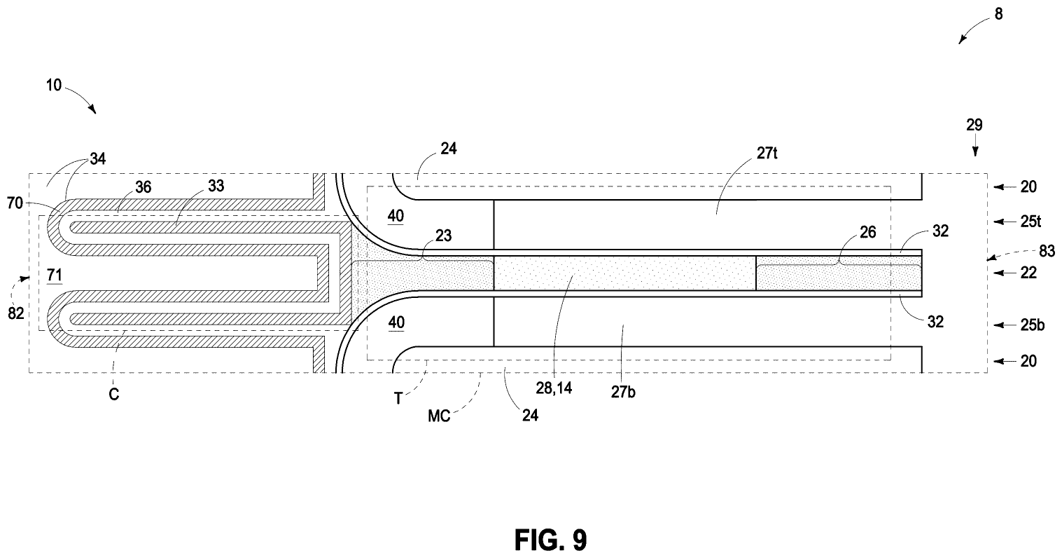

Referring to FIGS. 8 and 9, vertically-alternating insulative tiers 20 and memory-cell tiers 22 have been formed and have an opening 29 extending vertically there-through. Example capacitors C and example source/drain regions 23 and 26 are shown as already having been formed, although any of such could be formed later in processing not material to aspects of the inventions disclosed herein. Regardless, example manners not material to the inventions disclosed herein in forming that which is shown herein are, for example, shown in Micron Technology's U.S. Patent Application Publication Nos. 2022/0254784, 2022/0130834, U.S. Pat. No. 11,342,218, etc. Regardless, memory-cell tiers 22 individually comprise an access-line tier 25* that is vertically between a top insulating material and a bottom insulating material (e.g., 24 and 32 for a top access line 25t, respectively, and 32 and 24 for a bottom access line 25b, respectively). Access-line tiers 25* individually comprise a void-space 27* (e.g., a top void-space 27t and a bottom void-space 27b) between the top and bottom insulating materials and that extends to opening 29.

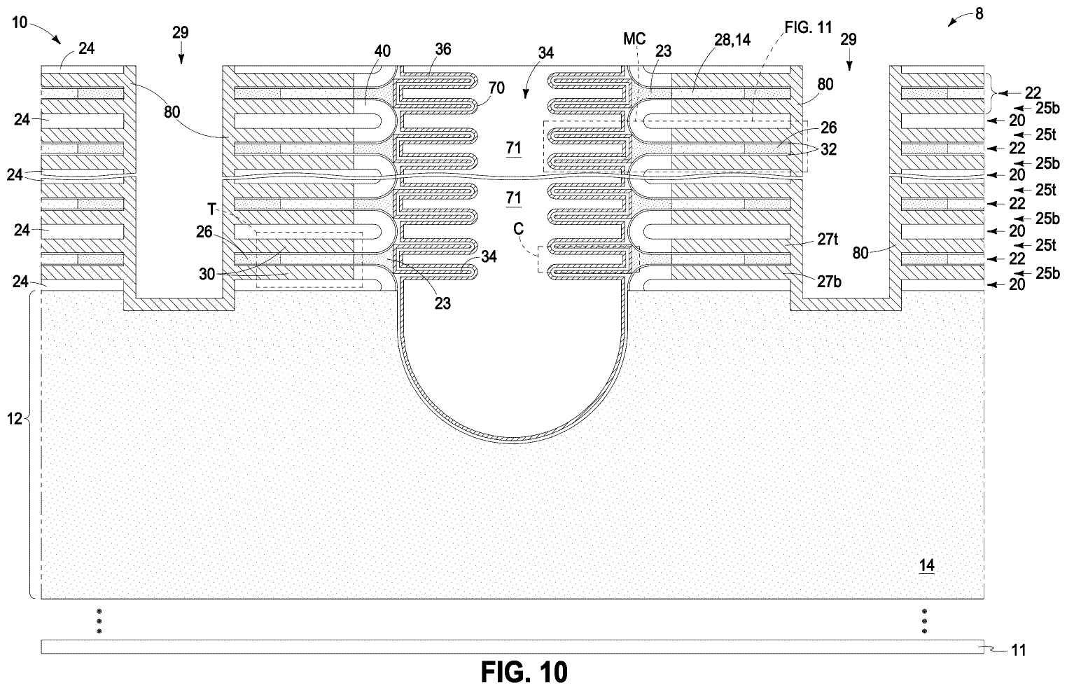

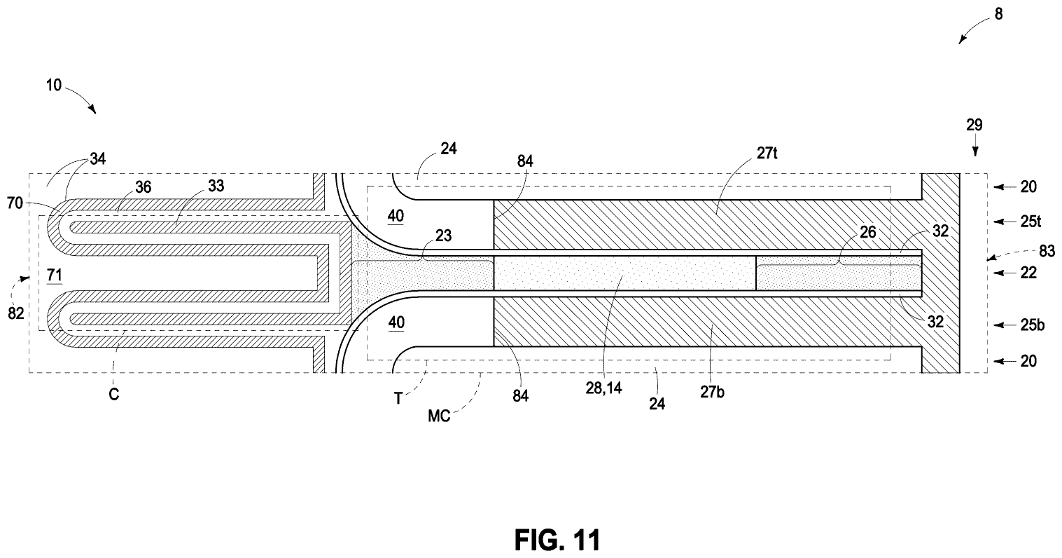

Referring to FIGS. 10 and 11, through opening 29, conductive first metal material 80 has been formed in void-space 27* (e.g., 27t and 27b) in individual access-line tiers 25* (e.g., 25t and 25b). In one embodiment and as shown, conductive first metal material 80 is formed to completely fill void-space 27*. In one embodiment and as shown, a laterally-innermost extent 84 of void-space 27* away from opening 29 is defined by an insulator material (e.g., 40) directly against which conductive first metal material 80 is formed.

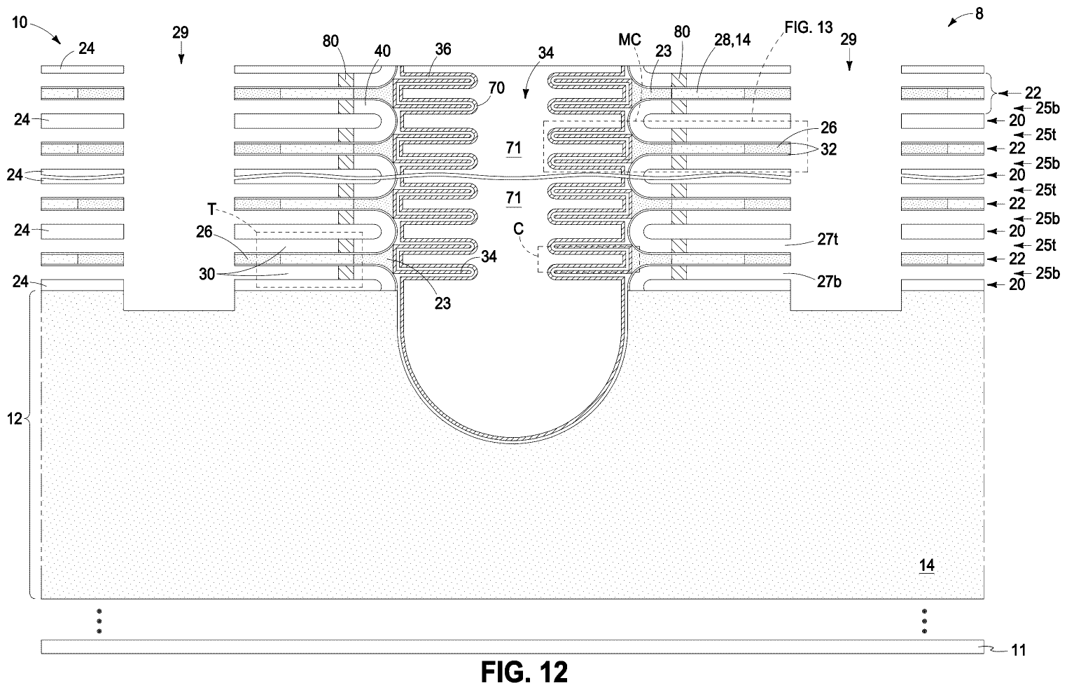

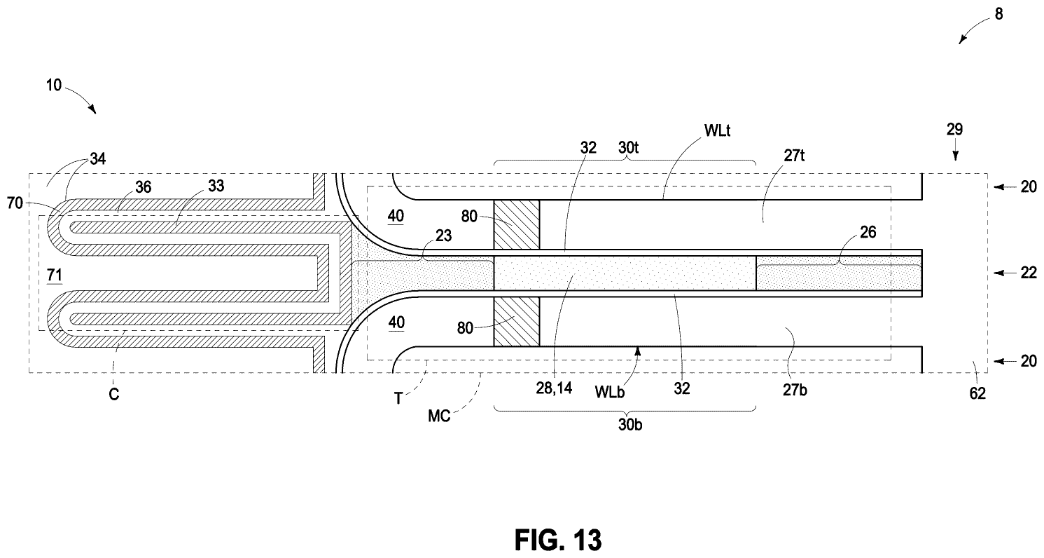

Referring to FIGS. 12 and 13, conductive first metal material 80 in individual access-line tiers 25* (e.g., 25t and 25b) has been laterally recessed (e.g., by selective isotropic wet or dry etching; e.g., to a final desired volume and position).

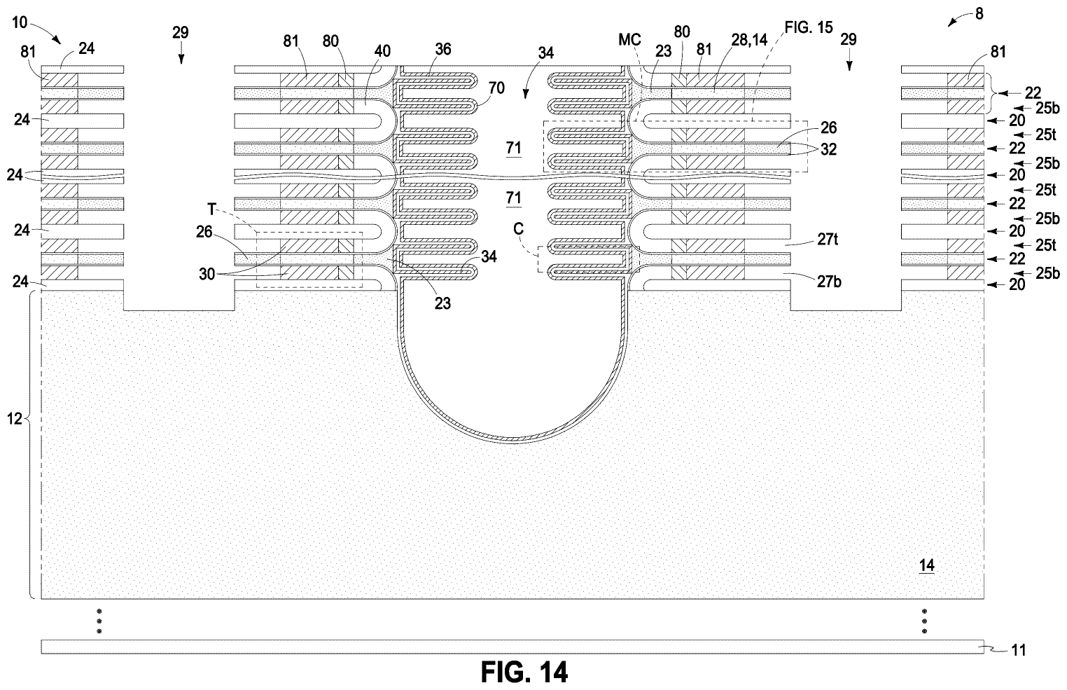

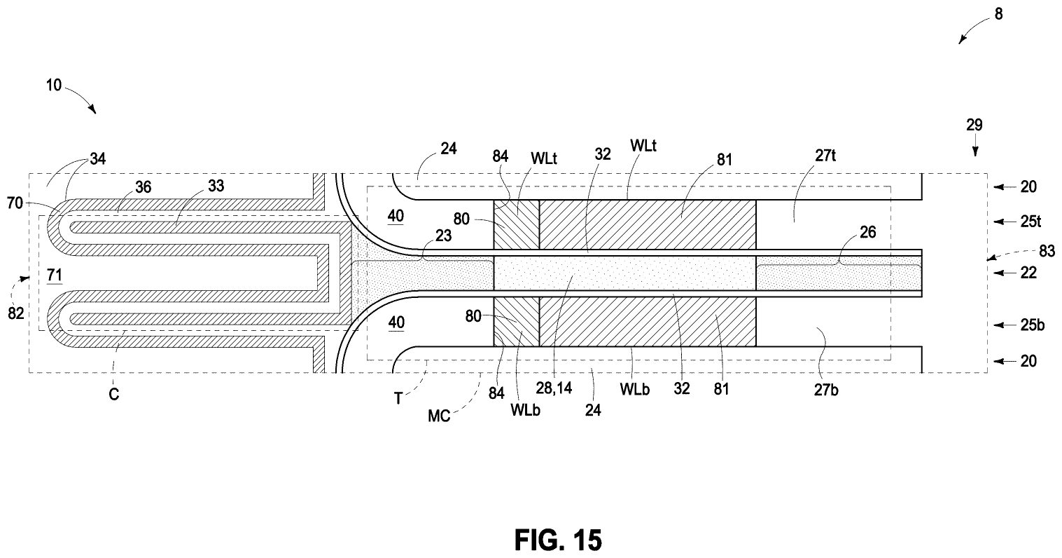

Referring to FIGS. 14 and 15, through opening 29, conductive second metal material 81 has been formed in individual access-line tiers 25* (e.g., 25t and 25b) laterally aside and directly against laterally-recessed conductive first metal material 80. Conductive first and second metal materials 80 and 81 comprise different compositions relative one another and comprise individual access lines WL* (e.g., WLt and WLb) comprising a gate 30* (e.g., 30t and 30b) of individual horizontal transistors T. Ideally, conductive second metal material 81 is selectively grown from laterally-recessed conductive first metal material 80. The artisan is able to select suitable conditions for selectively growing a selected second metal material 81 from a selected conductive first metal material 80. For example, and by way of example only, where first metal material 80 is titanium nitride and second metal material 81 is elemental-form molybdenum, example precursors are MoO₂Cl₂, MoCl₅, and MoOCl₄ (at least one), H₂, and Ar at 300° C. to 800° C. and pressure of 500 mTorr to 200 Torr. If such extends into opening 29, such can be removed back (e.g., by etching) relative to opening 29. Alternatively, but less desirable, conductive second metal material 81 could be non-selectively formed and removed back (e.g., by etching) analogously to the above example method of forming conductive first metal material 80. In one embodiment, through opening 29, insulator material (e.g., 40) can then be formed in remaining volume of void-space 27* (e.g., 27t and 27b) directly against selectively-grown conductive second metal material 81.

Any other attribute(s) or aspect(s) as shown and/or described herein with respect to other embodiments may be used.

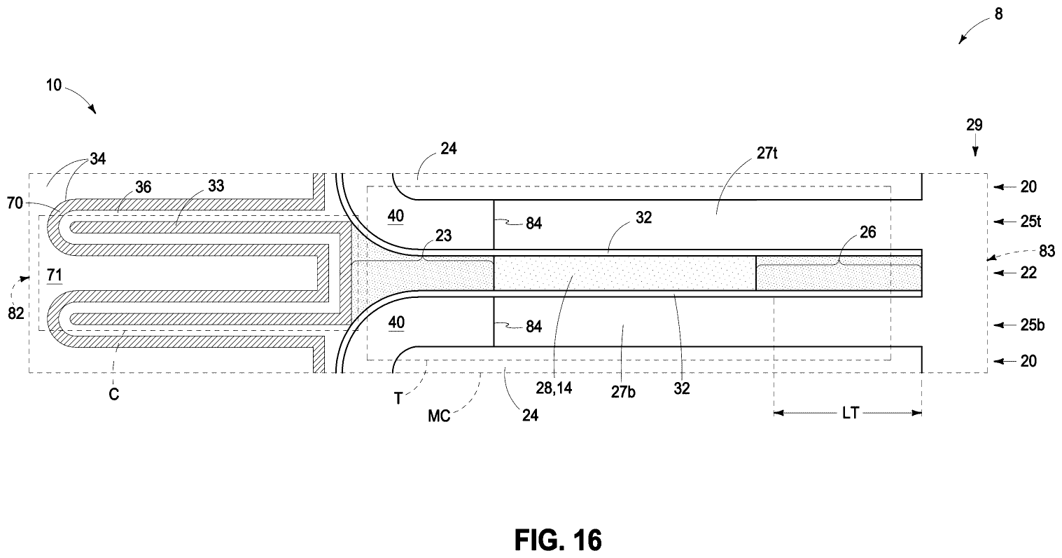

FIGS. 16-20 by way of example sequentially show predecessor constructions 8 in a second example method used in forming memory circuitry, with such circuitry comprising memory cells that individually comprise a horizontal transistor.

Referring to FIG. 16, a laterally-innermost extent 84 of void-space 27* away from opening 29 is defined by an insulator material (e.g., 40).

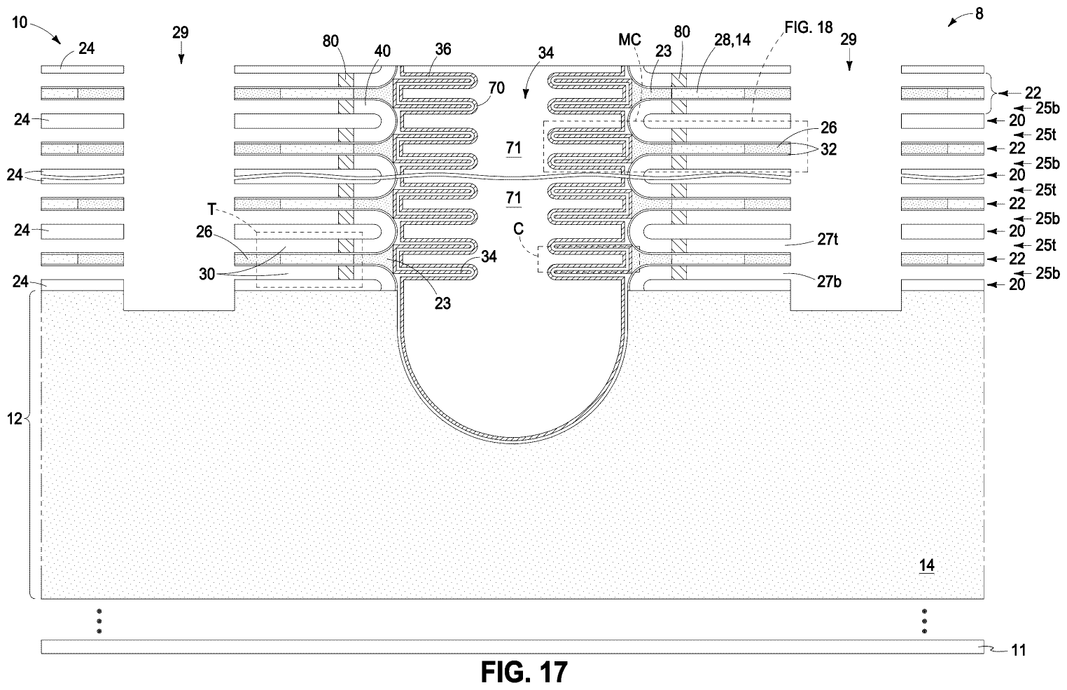

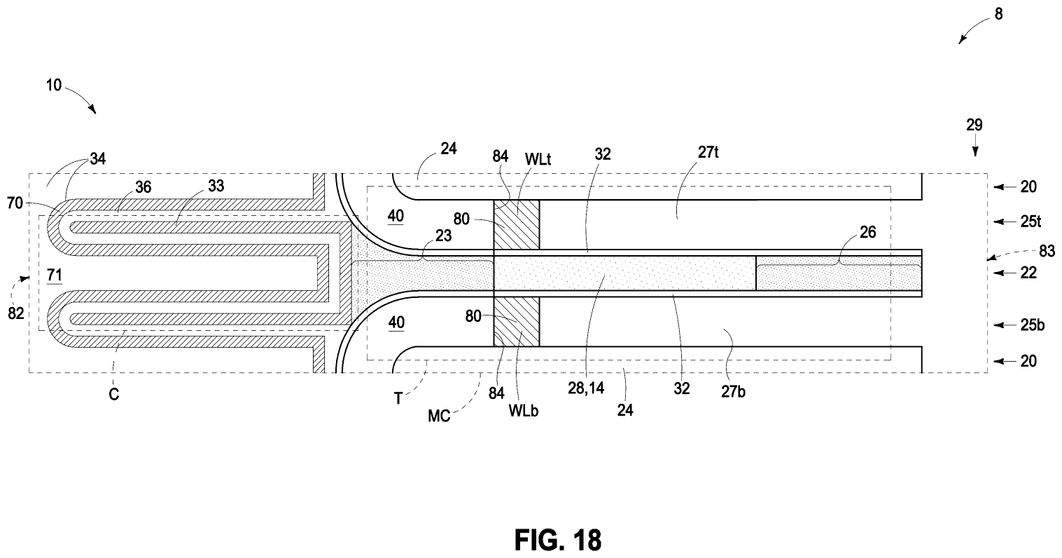

Referring to FIGS. 17 and 18, through opening 29, conductive first metal material 80 has been selectively grown in void-space 27* laterally aside, directly against, and laterally from insulator material 40 in individual access-line tiers 25*. The artisan is able to select suitable conditions for selectively growing a selected conductive first metal material 80 from a selected insulator material 40. For example, and by way of example only, where conductive first metal material 80 is titanium nitride and insulator material 40 is silicon nitride, example precursors are TiCl₄, TiBr₄, and tetrakis(dimethylamino)titanium (TDMAT) (at least one) and NH₃ at 300° C. to 800° C. and pressure of 500 mTorr to 150 Torr. Ideally, the selective growth of conductive first metal material 80 is to a desired finished volume of such (as shown) such that no etch-back thereof is needed.

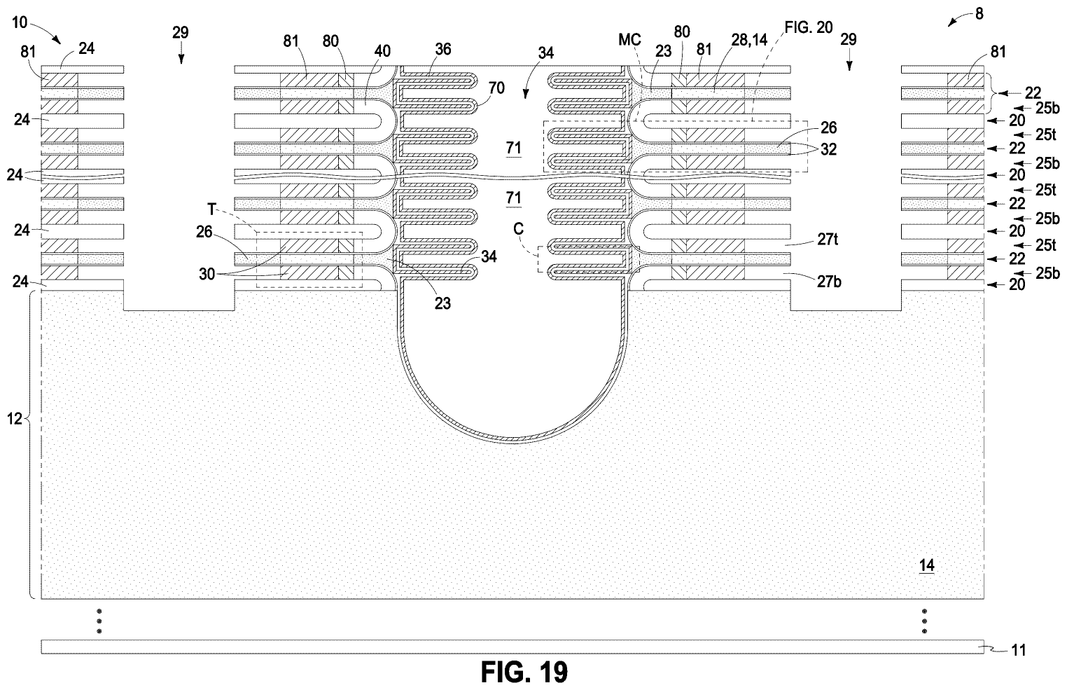

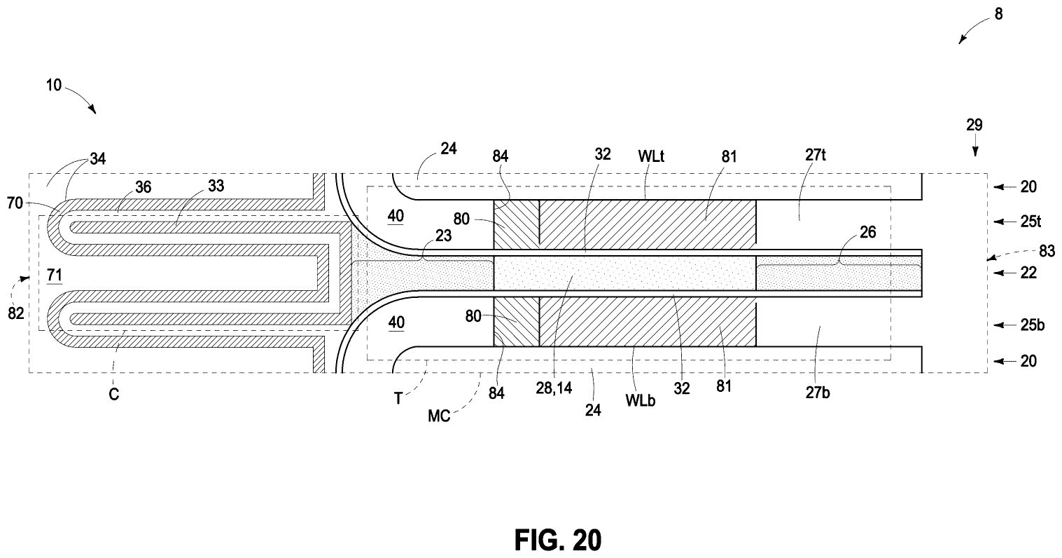

Referring to FIGS. 19 and 20, through opening 29, conductive second metal material 81 has been formed in individual access-line tiers 25* laterally aside and directly against selectively-grown conductive first metal material 80. Conductive first and second metal materials 80 and 81 comprise different compositions relative one another and comprise individual access lines WL* comprising a gate 30* of individual horizontal transistors T. Ideally, conductive second metal material 81 is selectively grown from selectively-grown conductive first metal material 80, for example as described above, and ideally to a desired finished volume of such (as shown) such that no etch-back thereof is needed. Regardless, insulator material 40 may subsequently be formed in remaining volume of void-space 27*.

Any other attribute(s) or aspect(s) as shown and/or described herein with respect to other embodiments may be used.

Embodiments of the invention may be used to mitigate tier bending issues during metal fills for the access lines, reduce porosity formation in such metal fills, and reduce overall access line resistance.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### Conclusion

In some embodiments, a method used in forming memory circuitry that comprises memory cells that individually comprise a horizontal transistor comprises forming vertically-alternating insulative tiers and memory-cell tiers having an opening extending vertically there-through. The memory-cell tiers individually comprise an access-line tier that is vertically between top and bottom insulating materials. The access-line tiers individually comprise a void-space between the top and bottom insulating materials and that extends to the opening. Through the opening, a conductive first metal material is formed in the void-space in individual of the access-line tiers. The conductive first metal material is laterally recessed in the individual access-line tiers. Through the opening, a conductive second metal material is formed in the individual access-line tiers laterally aside and directly against the laterally-recessed conductive first metal material. The conductive first and second metal materials comprise different compositions relative one another and comprise individual access lines comprising a gate of individual of the horizontal transistors.

In some embodiments, a method used in forming memory circuitry comprising memory cells that individually comprise a horizontal transistor comprises forming vertically-alternating insulative tiers and memory-cell tiers having an opening extending vertically there-through. The memory-cell tiers individually comprise an access-line tier that is vertically between top and bottom insulating materials. The access-line tiers individually comprise a void-space between the top and bottom insulating materials and that extends to the opening. A laterally-innermost extent of the void-space away from the opening is defined by an insulator material. Through the opening, a conductive first metal material is selectively grown in the void-space laterally aside, directly against, and laterally from the insulator material in individual of the access-line tiers. Through the opening, a conductive second metal material is formed in the individual access-line tiers laterally aside and directly against the selectively-grown conductive first metal material. The conductive first and second metal materials comprise different compositions relative one another and comprise individual access lines comprising a gate of individual of the horizontal transistors.

In some embodiments, memory circuitry comprises vertically-alternating tiers of insulative material and memory cells. The memory cells individually comprise a horizontal transistor comprising a gate. The gate comprises part of a one of a plurality of horizontal conductive access lines that individually directly electrically couple together multiple of the gates of different ones of the horizontal transistors that are in the same memory-cell tier. The gates and access lines individually comprise conductive first and second different composition metal materials that are laterally aside and directly against one another.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry comprising memory cells that individually comprise a horizontal transistor, the method comprising:
forming vertically-alternating insulative tiers and memory-cell tiers having an opening extending vertically there-through, the memory-cell tiers individually comprising an access-line tier that is vertically between top and bottom insulating materials, the access-line tiers individually comprising a void-space between the top and bottom insulating materials and that extends to the opening;
through the opening, forming a conductive first metal material in the void-space in individual of the access-line tiers;
laterally-recessing the conductive first metal material in the individual access-line tiers; and
through the opening, forming a conductive second metal material in the individual access-line tiers laterally aside and directly against the laterally-recessed conductive first metal material; the conductive first and second metal materials comprising different compositions relative one another and comprising individual access lines comprising a gate of individual of the horizontal transistors.

2. The method of claim 1 wherein the conductive second metal material is selectively grown from the laterally-recessed conductive first metal material.

3. The method of claim 2 wherein the conductive first metal material comprises titanium nitride and the conductive second metal material comprises elemental-form molybdenum.

4. The method of claim 2 comprising, through the opening, forming insulator material in remaining volume of the void-space directly against the selectively-grown conductive second metal material.

5. The method of claim 1 wherein the conductive first metal material is formed to completely fill the void-space prior to the laterally-recessing.

6. The method of claim 1 wherein a laterally-innermost extent of the void-space away from the opening is defined by an insulator material directly against which the conductive first metal material is formed.

7. The method of claim 1 wherein at least one of the conductive first and second metal materials spans a total thickness of individual of the gates and access lines.

8. The method of claim 7 wherein each of the conductive first and second metal materials spans the total thickness of the individual gates and access lines.

9. The method of claim 1 wherein the conductive first and second metal materials have different volumes relative one another.

10. The method of claim 9 wherein the memory cells individually comprise two laterally-opposing sides, one of the sides comprising a capacitor, the transistor on the other of the sides being directly electrically coupled to a digitline, the larger of the two volumes being closer to the digitline than to the capacitor.

11. The method of claim 10 wherein the conductive second metal material has greater electrical conductivity than the conductive first metal material, the conductive second metal material being the larger of the two volumes.

12. The method of claim 10 wherein the one of the conductive first and second conductive metal materials comprises elemental-form molybdenum and the other comprises titanium nitride, the larger of the two volumes comprising the elemental-form molybdenum and the smaller of the two volumes comprising the titanium nitride.

13. The method of claim 1 wherein,
the memory-cell tiers individually comprise a top access-line tier that is vertically between the top and bottom insulating materials and comprise a bottom access-line tier that is vertically between the top and bottom insulating materials, the top access-line tiers individually comprise a top void-space between the top and bottom insulating materials and that extends to the opening, the bottom access-line tiers individually comprise a bottom void-space between the top and bottom insulating materials and that extends to the opening;
the conductive first metal material is formed in the top and bottom void-spaces;
the conductive first metal material is laterally recessed in individual of the top and bottom access-line tiers; and
the conductive second metal material is formed in the individual top and bottom access-line tiers laterally aside and directly against the laterally-recessed conductive first metal material, the individual access lines comprising a top access line and a bottom access line, the conductive first and second metal materials being laterally aside and directly against one another in each of the top and bottom access lines.

14. A method used in forming memory circuitry comprising memory cells that individually comprise a horizontal transistor, the method comprising:
forming vertically-alternating insulative tiers and memory-cell tiers having an opening extending vertically there-through, the memory-cell tiers individually comprising an access-line tier that is vertically between top and bottom insulating materials, the access-line tiers individually comprising a void-space between the top and bottom insulating materials and that extends to the opening, a laterally-innermost extent of the void-space away from the opening being defined by an insulator material;
through the opening, selectively growing a conductive first metal material in the void-space laterally aside, directly against, and laterally from the insulator material in individual of the access-line tiers; and
through the opening, forming a conductive second metal material in the individual access-line tiers laterally aside and directly against the selectively-grown conductive first metal material; the conductive first and second metal materials comprising different compositions relative one another and comprising individual access lines comprising a gate of individual of the horizontal transistors.

15. The method of claim 14 wherein the insulator material comprises silicon nitride and the conductive first metal material comprises titanium nitride.

16. The method of claim 14 wherein the conductive second metal material is selectively grown from the selectively-grown conductive first metal material.

17. The method of claim 16 comprising, through the opening, forming insulator material in remaining volume of the void-space directly against the selectively-grown conductive second metal material.

18. The method of claim 14 wherein the conductive first metal material comprises titanium nitride and the conductive second metal material comprises elemental-form molybdenum.

19. The method of claim 18 wherein the insulator material comprises silicon nitride.

20. Memory circuitry comprising:
vertically-alternating tiers of insulative material and memory cells, the memory cells individually comprising a horizontal transistor comprising a gate, the gate comprising part of a one of a plurality of horizontal conductive access lines that individually directly electrically couple together multiple of the gates of different ones of the horizontal transistors that are in the same memory-cell tier; and
the gates and access lines individually comprising conductive first and second different composition metal materials that are laterally aside and directly against one another.
